(19) United States
(12) Patent Application Publication
(10) Pub. No.: US 2002/0141467 A1
(43) Pub. Date: Oct. 3, 2002

(54) Semiconductor laser device

(75) Inventors: Norihiro Iwai, Tokyo (JP); Masaki Funabashi, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: THE FURUKAWA ELECTRIC CO., LTD, Chiyoda-ku (JP)

(21) Appl. No.: 09/930,130

(22) Filed: Aug. 16, 2001

(30) Foreign Application Priority Data
Apr. 2, 2001 (JP) 2001-103966

(51) Int. Cl. H01S 5/00

(52) U.S. Cl. 372/45; 372/46

(57) ABSTRACT

The semiconductor laser device the n-InP cladding layer, SCH-MQW active layer, p-InP cladding layer, and p-GaInAsP optical waveguide layer are respectively formed into a tapered shape on the n-InP substrate. The combination of oscillation parameters of the tapered shape, the grating pitch of a diffraction grating, an optical waveguide including an active layer, and the length of a resonator are adjusted so that laser beam including two or more oscillating longitudinal modes are output.

### FIELD OF THE INVENTION

The present invention relates to a semiconductor laser device that has two or more oscillating longitudinal modes and that emits laser beam suitable for a Raman amplifying light source.

### BACKGROUND OF THE INVENTION

The demand for an increase in the capacity of the optical communication has been recently increasing in accordance with the spread of various multimedia including the Internet. Optical communication has conventionally used transmission by a single wavelength in a band of 1310 nm (nano-meter) or 1550 nm. Light is less absorbed by an optical fiber in general in this wavelength band. However, there is a disadvantage that it is necessary to increase the number of cores of the optical fiber to be laid on a transfer line in order to transmit a large volume of information. As a consequence, the cost increases as the transmission capacity is increased.

The wavelength division multiplexing (WDM) communication method may be used to overcome this problem. This WDM communication method performs transmission by mainly using a nerbium-doped fiber amplifier (EDFA) and using a plurality of wavelengths in a band of 1550 nm range that is the gain band width of the amplifier. Because the WDM communication method simultaneously transmits optical signals having a plurality of different wavelengths by using one optical fiber, it is unnecessary to lay a new line and it is possible to extremely increase the transmission capacity of a network.

For the general WDM communication method using the EDFA, a band of 1550 nm whose gain can be easily flattened is practically used and a band is recently extended up to 1580 nm which has not been used because of a small gain coefficient. However, because the low-loss band of an optical fiber is wider than a band which can be amplified by the EDFA, the interest in an optical amplifier operating in a band out of the band of the EDFA, that is, a Raman amplifier is raised.

In the Raman amplifier, a gain appears in a wavelength approximately 100 nm longer than an excited-light wavelength due to induced Raman scattering by receiving excited light strong in an optical fiber and when applying signal light in a wavelength band having the above gain to the excited optical fiber, the signal light is amplified. Therefore, when the Raman amplifier is used in the WDM communication method, it is possible to further increase the number of channels of signal light in which a gain wavelength band is expanded compared to the case of a communication method using an EDFA.

FIG. 18 is an illustration showing a configuration of a conventional laser device for emitting a laser beam used for a Raman amplifier. This laser device has a semiconductor light-emitting diode 202 and an optical fiber 203. The semiconductor light-emitting diode 202 has an active layer 221. The active layer 221 has a high reflective coating 222 at its one end and a anti-reflective coating 223 at its other end. The light produced in the active layer 221 reflects from the high reflective coating and is output from the anti-reflective coating 223.

The optical fiber 203 is set to the anti reflective coating 223 of the semiconductor light-emitting diode 202 and combined with a laser beam emitted from the anti reflective coating 223. A fiber grating 233 is formed at a predetermined position of a core 232 in the optical fiber 203 separate from the anti reflective coating 223 and the fiber grating 233 selectively reflects specified-wavelength light. That is, the fiber grating 233 functions as an external resonator, forms a resonator between the fiber grating 233 and the high reflective coating 222 and the specified-wavelength light selected by the fiber grating 233 is amplified and output as a laser beam 241.

Moreover, a laser-beam source used for a Raman amplifier may have used a distribute feedback (DFB) semiconductor laser. The DFB semiconductor laser performs stable single longitudinal-mode oscillation without using an optical fiber grating because of setting a diffraction grating nearby an active layer.

In the conventional semiconductor laser device, however, the relative intensity noise (RIN) increases due to the resonation between the fiber grating 233 and the high reflective coating 222 because the interval between the fiber grating 233 and the semiconductor light-emitting diode 202 is large. Raman amplification has a problem that it is difficult to obtain stable Raman amplification because the process of amplification early occurs and thereby, Raman gain fluctuates when an excited-light intensity fluctuates and the fluctuation of the Raman gain is directly amplified and output as the fluctuation of signal intensity.

Moreover, there is a problem that it is difficult to provide stable excited light because it is necessary to optically combine the optical fiber 203 having the fiber grating 233 with the semiconductor light-emitting diode 202 and oscillation characteristics of a laser may be changed due to mechanical vibrations.

However, when using a distribution feedback semiconductor laser, problems occur that it is difficult to obtain a high-output laser beam and excite an optical fiber at a high output because a laser beam oscillates in a single longitudinal mode. Moreover, a laser beam in a single-longitudinal mode has problems that induced Brillouin scattering occurs exceeding the threshold of induced Brillouin scattering under Raman amplification and noises increase.

### SUMMARY OF THE INVENTION

It is an object of the present invention to provide a semiconductor laser device suitable for a Raman amplifying light source capable of obtaining a stable and high gain.

The semiconductor laser according to one aspect of this invention comprises a continuous tapered shaped mesa-stripe portion and outputs the laser beam including two or more oscillating longitudinal modes in accordance with combination setting of oscillation parameters of the taper of the mesa-stripe portion, the grating pitch of the diffraction grating, the optical waveguide including the active layer, and the length of the resonator.

The semiconductor laser according to another aspect of this invention comprises a step-like tapered shaped mesa-stripe portion and outputs the laser beam including two or more oscillating longitudinal modes in accordance with combination setting of oscillation parameters of the taper of the mesa-stripe portion, the grating pitch of the diffraction grating, the optical waveguide including the active layer, and the length of the resonator.

The semiconductor laser according to still another aspect of this invention comprises a continuous tapered shaped ridge portion and outputs the laser beam including two or more oscillating longitudinal modes in accordance with combination setting of oscillation parameters of the taper of the ridge portion, the grating pitch of the diffraction grating, the optical waveguide including the active layer, and the length of the resonator.

The semiconductor laser according to still another aspect of this invention comprises a step-like tapered shaped ridge portion and outputs the laser beam including two or more oscillating longitudinal modes by combining and setting oscillation parameters of the taper of the ridge portion, the grating pitch of the diffraction grating, the optical waveguide including the active layer, and the length of the resonator.

The semiconductor laser according to still another aspect of this invention comprises an current confinement layer constituted of the tapered oxide film having a continuous tapered shaped opening and outputs the laser beam including two or more oscillating longitudinal modes by combining and setting oscillation parameters of the opening of the current confinement layer, the grating pitch of the diffraction grating, the optical waveguide in the active layer, and the length of the resonator.

The semiconductor laser according to still another aspect of this invention comprises an current confinement layer constituted of the tapered oxide film having a continuous step-like tapered shaped opening and outputs the laser beam including two or more oscillating longitudinal modes by combining and setting oscillation parameters of the opening of the current confinement layer, the grating pitch of the diffraction grating, the optical waveguide including the active layer, and the length of the resonator.

Other objects and features of this invention will become apparent from the following description with reference to the accompanying drawings.

### BRIEF DESCRIPTION OF THE DRAWINGS

FIG. 1 is a perspective view showing a configuration of a semiconductor laser device of first embodiment of the present invention;

FIG. 2 is a sectional view of the semiconductor laser device shown in FIG. 1 in the direction vertical to the resonator direction of the system;

FIG. 3 is a sectional view of the semiconductor laser device shown in FIG. 2, taken along the line A-A in FIG. 2;

FIG. 4 is an illustration showing the relation between the oscillation wavelength spectrum and the oscillating longitudinal mode of the semiconductor laser device shown in FIG. 1;

FIG. 5 is an illustration for explaining the dependence of effective refraction index on active layer width;

FIG. 6A and FIG. 6B are illustrations showing the relation of laser-beam output between a single oscillating longitudinal mode and a plurality of oscillating longitudinal modes and the threshold of induced Brillouin scattering;

FIG. 7 is a sectional view of the semiconductor laser device shown in FIG. 2, taken along the line A-A in FIG. 2 when forming a part of a mesa stripe portion into a tapered shape;

FIG. 8 is a sectional view of the semiconductor laser device shown in FIG. 2, taken along the line A-A in FIG. 2 when stepwise changing widths of a mesa stripe portion;

FIG. 9 is a perspective view showing a schematic configuration of a semiconductor laser device that is second embodiment of the present invention;

FIG. 10 is a sectional view of the semiconductor laser device shown in FIG. 9 in the direction vertical to the resonator direction of the system;

FIG. 11 is a sectional view of the semiconductor laser device shown in FIG. 10, taken along the line B-B in FIG. 10;

FIG. 12 is a perspective view showing a schematic configuration of a semiconductor laser device that is third embodiment of the present invention;

FIG. 13 is a sectional view of the semiconductor laser device shown in FIG. 2 in the direction vertical to the resonator direction of the system;

FIG. 14 is a sectional view of the semiconductor laser device shown in FIG. 13, taken along the line C-C in FIG. 13;

FIG. 15 is a perspective view showing a schematic configuration of a semiconductor laser device that is fourth embodiment of the present invention;

FIG. 16 is a sectional view of the semiconductor laser device shown in FIG. 15 in the direction vertical to the resonator direction of the system;

FIG. 17 is a sectional view of the semiconductor laser device shown in FIG. 16, taken along the line D-D in FIG. 16; and

FIG. 18 is an illustration showing a configuration of a conventional laser device with FBG for emitting a laser beam used for a Raman amplifier.

### DESCRIPTION OF THE PREFERRED EMBODIMENTS

Embodiments of a semiconductor laser device of the present invention are described below by referring to the accompanying drawings.

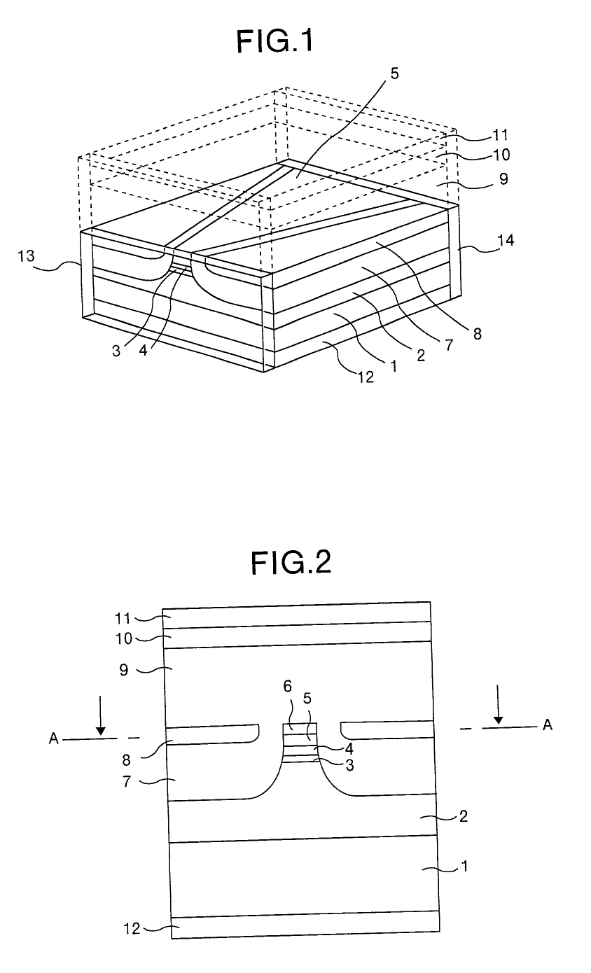

FIG. 1 is a perspective view showing a schematic configuration of the semiconductor laser device of a first embodiment of the present invention. Moreover, FIG. 2 is a sectional view of the semiconductor laser device shown in FIG. 1 in the direction vertical to the direction of the resonator of the system. Furthermore, FIG. 3 is a sectional view of the semiconductor laser device in FIG. 2, taken along the line A-A of FIG. 2. As shown in these figures, the semiconductor laser device is constituted by forming an n-InP cladding layer 2, an SCH-MQW active layer 3, a p-InP cladding layer 4, a p-GaInAsP optical waveguide layer 5 with a diffraction grating formed on it, and a p-InP layer 6 on an n-InP substrate 1 in order, and thereby forming a mesa-stripe portion. Furthermore, a p-InP layer 7 and an n-InP layer 8 are formed on side faces of the mesa-stripe portion. Furthermore, a p-InP cladding layer 9 and a p-GaInAs contact layer 10 are formed in order on the upper face of the mesa-stripe portion.

Furthermore, a p-side electrode 11 is formed on the upper face of the p-GaInAs contact layer 10 and an n-side electrode 12 is formed on the back of the n-InP substrate 1. Furthermore, an emission-side reflective coating 13 having a low light reflectance of 1% or less is formed on the light emission facet (i.e. facet from where light is emitted) which is one facet of the semiconductor laser device and a reflective coating 14 having a high reflectance of 70% or more is formed on the light reflection facet (i.e. facet from where light is reflected) which is the other facet of the semiconductor laser device. Furthermore, the mesa-stripe portion formed by the n-InP cladding layer 2, SCH-MQW active layer 3, p-InP cladding layer 4, p-GaInAsP optical waveguide layer 5, and p-InP layer 6 has a thick tapered shape whose mesa width decreases nearby the emission-side reflective coating 13 and increases nearby the reflective coating 14.

In this case, the light produced in the SCH-MQW active layer 3 formed between the emission-side reflective coating 13 and the reflective coating 14 is reflected from the reflective coating 14 and emitted as a laser beam through the emission-side reflective coating 13. Therefore, it is possible to efficiently obtain the laser beam from the emission-side reflective coating 13. Moreover, the laser beam can output a laser beam including two or more oscillating longitudinal modes by combining and setting oscillation parameters of a tapered shape, the grating pitch of a diffraction grating, the p-GaInAsP optical waveguide layer 5, and the length of a resonator.

The semiconductor laser device of the first embodiment is fabricated in a manner as explained below. First, the n-InP cladding layer 2, SCH-MQW active layer 3, p-InP cladding layer 4, p-GaInAsP optical waveguide layer 5, and p-InP layer 6 are formed in order on the n-InP substrate 1 grown by MOCVD. Then, a grating having a predetermined pitch is patterned by an electron-beam exposure system to form a diffraction grating on the p-GaInAsP optical waveguide layer 5 and p-InP layer 6 through chemical etching.

Moreover, the diffraction grating formed on the p-GaInAsP waveguide layer 5 grown by MOCVD is flatly embedded by the p-InP layer 6. Then, a tapered SiNx film is formed and up to the middle of the n-InP cladding layer is etched through a bromine-based etching solution by using the SiNx film as a mask to form the tapered shape shown in FIG. 3. Thereafter, by directly using the tapered SiNx film as a selective-growth mask, the p-InP layer 7 and n-InP layer 8 are formed on side faces of the mesa-stripe portion grown by MOCVD.

Then, the SiNx film is removed to form the p-InP cladding layer 9 and p-GaInAs contact layer 10 grown by MOCVD. Moreover, the p-side electrode 11 is formed on the upper face of the p-GaInAs contact layer 10 and the n-InP substrate 1 is polished up to a thickness of approximately 100 μm to form the n-side electrode 12 on the back of the substrate 1. Then, the substrate is cleaved to form the emission-side reflective coating 13 having a low light reflectance of 1% or less on the light emission facet. Moreover, the reflective coating 14 having a high light reflectance of 70% or more is formed on the light reflection facet.

Then, the oscillating longitudinal mode of a laser beam emitted from the semiconductor laser device of the first embodiment is described below. In general, the interval Δλ between longitudinal modes generated by a resonator of a semiconductor laser device is shown as Δλ=(λ₀)²/(2nL) by using oscillation wavelength λ₀, refractive index n, and resonator length L. That is, as the oscillation wavelength L increases, the interval between longitudinal modes decreases. Therefore, it is possible to easily obtain multiple-mode oscillation from a DFB laser.

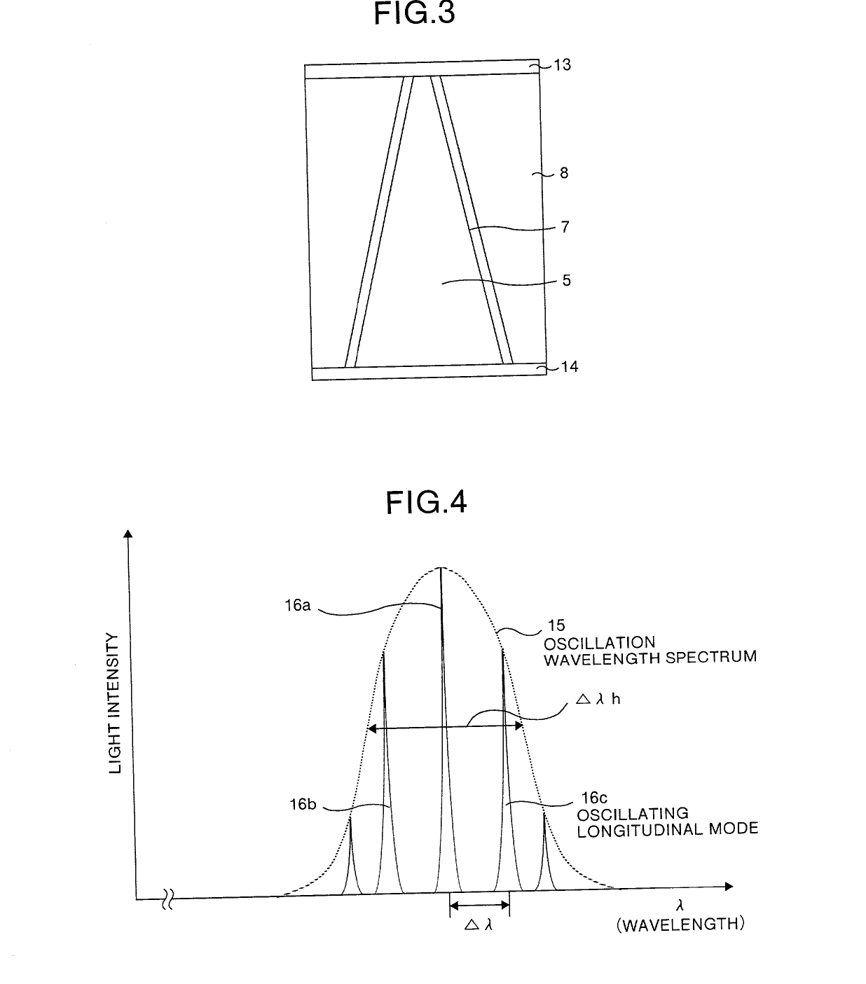

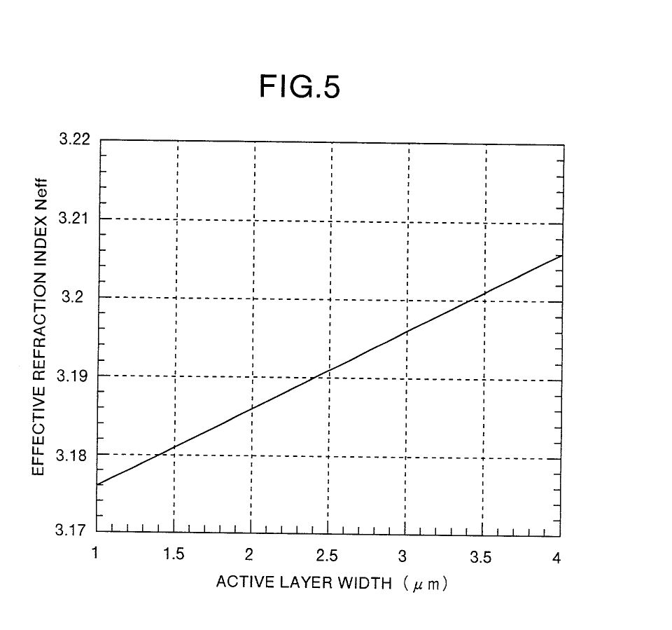

However, a diffraction grating selects an oscillation wavelength in accordance with its Bragg reflection. Wavelength selectivity by the diffraction grating may be represented as λ₀=2NeffΛ where λ₀ is the oscillation wavelength, Neff is the effective refractive index, and A is the grating pitch of a diffraction grating. Moreover, the longitudinal mode selected by the diffraction grating is shown as the oscillating wavelength spectrum 15 shown in FIG. 4 and the longitudinal mode present in the half band width Δλh of the oscillating wavelength spectrum 15 is oscillated. The oscillating wavelength spectrum 15 is decided in accordance with the grating pitch of a diffraction grating and the effective refractive index Neff. The effective refractive index Neff fluctuates depending on the width of an active layer as shown in FIG. 5. For example, when the width of the active layer is equal to 1 μm, the effective refractive index Neff becomes 3.176. However, when the width of the active layer is equal to 4 μm, the effective refractive index Neff becomes 3.206. This value is slightly changed depending on the structure of the active layer. Thus, because the effective refractive index Neff depends on the width of the active layer, the oscillating wavelength depends on the width of the active layer.

In the case of the semiconductor laser device of this first embodiment, because the mesa-stripe portion is formed into a tapered shape, widths of the SCH-MQW active layer 3 change in a range of 0.5 to 2 μm. Thereby, because values of the effective refractive index Neff change in the resonator direction, multiple-mode oscillation is realized.

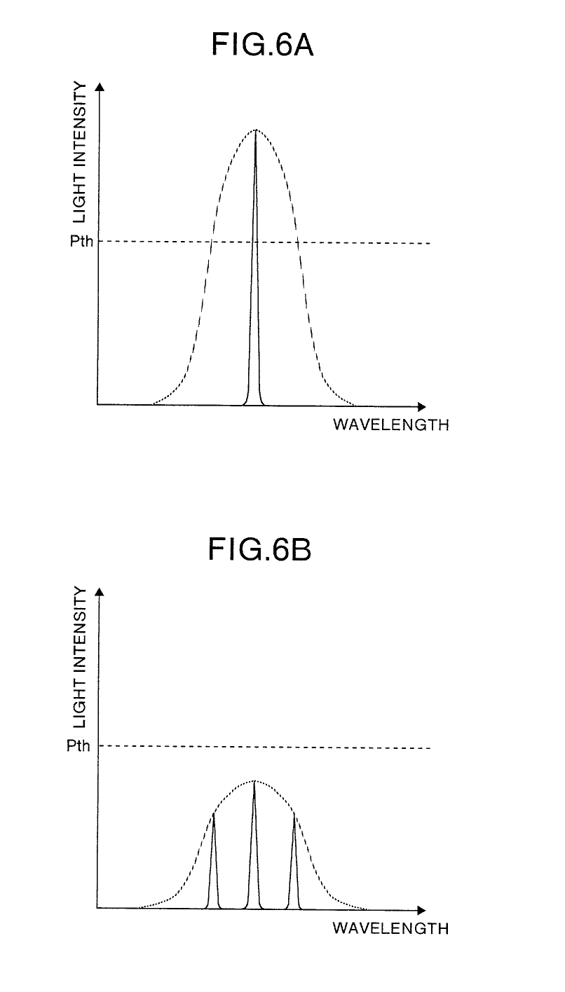

In the case of the semiconductor laser device of the first embodiment, by setting the grating pitch of a diffraction grating and a tapered shape, it is possible to set the number of laser-beam oscillating longitudinal modes to a desired value. When using a laser beam having a plurality of oscillating longitudinal modes, it is possible to control the peak value of laser outputs and obtain a high laser output value compared to the case of using a laser beam in a single longitudinal mode. For example, the semiconductor laser device shown for the first embodiment has the profile shown in FIG. 6B and makes it possible to obtain a high laser output at a low peak value. On the contrary, FIG. 6A shows a profile of a semiconductor laser device of single longitudinal oscillation when obtaining the same laser output, in which a high peak value is shown.

In this case, it is preferable that the exciting light source of a Raman amplifier has a high output in order to increase a Raman gain. However, when the peak value of excited light is too high, problems occur that induced Brillouin scattering occurs and noises increase. The induced Brillouin scattering has a threshold Pth caused by the induced Brillouin scattering. Therefore, when obtaining the same laser output, it is possible to obtain a high excited-light output in the threshold Pth of the induced Brillouin scattering by providing a plurality of oscillating longitudinal modes and controlling the peak value of the modes as shown in FIG. 6B. As a result, it is possible to obtain a high Raman gain.

Moreover, because a conventional semiconductor laser device uses the semiconductor laser module using a fiber grating as shown in FIG. 18, the relative intensity noise (RIN) increases due to the resonation between the fiber grating 233 and the light reflective coating 222 and thereby, stable Raman amplification cannot be performed. In the case of the semiconductor laser device 202 shown for the first embodiment, however, it is possible to directly use a laser beam emitted from the emission-side reflective coating 14 as the exciting light source of a Raman amplifier instead of using the fiber grating 233. Therefore, the relative intensity noise decreases and as a result, the fluctuation of a Raman gain decreases and stable Raman amplification can be performed.

Moreover, because the semiconductor laser device shown in FIG. 18 requires mechanical combination in a resonator, oscillation characteristics of a laser may be changed due to vibration. In the case of the semiconductor laser device of the first embodiment, however, oscillation characteristics of a laser are not changed due to mechanical vibration and therefore, it is possible to obtain a stable light output.

Furthermore, in the case of the semiconductor laser device of the first embodiment, by setting the mesa width of the light emission side to 1 μm or less, light containment is weakened and a spot size expands. Therefore, it is possible to obtain a laser beam having a narrow emission beam shape and the combination efficiency with an optical fiber increases.

According to the semiconductor laser device of the first embodiment, the mesa-stripe portion formed by then-InP cladding layer 2, SCH-MQW active layer 3, p-InP cladding layer 4, p-GaInAsP optical waveguide layer 5 with a diffraction grating formed on it, and p-InP layer 6 is formed into a tapered shape and the grating pitch of the diffraction grating and the tapered shape are set so as to oscillate a laser beam including a plurality of oscillating longitudinal modes. Therefore, induced Brillouin scattering does not occur when using the mesa-stripe portion as the exciting light source of a Raman amplifier and a laser beam capable of obtaining a stable and high Raman gain is emitted.

Moreover, because optical coupling between an optical fiber having a fiber grating and a semiconductor light-emitting diode is not performed in a resonator like the case of a semiconductor laser device using a fiber grating, it is possible to avoid an unstable output due to mechanical vibration.

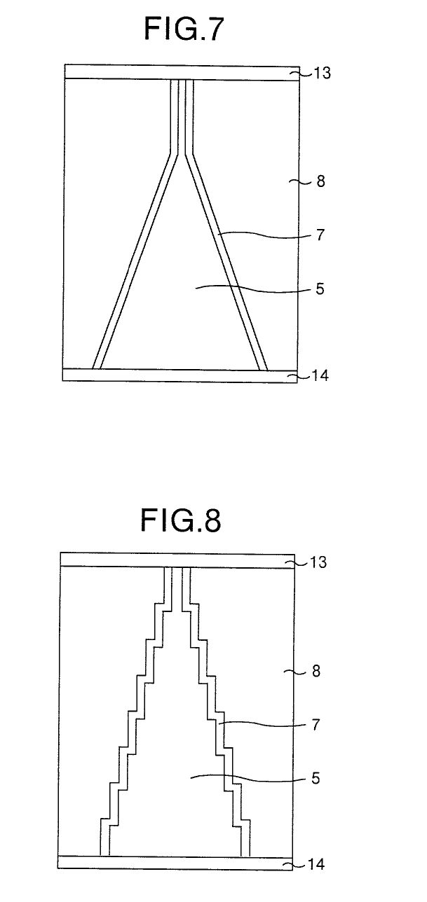

It is not always necessary to entirely form the mesa-stripe portion into a tapered shape as shown in FIG. 3. It is permitted to locally form the portion into a tapered shape as shown in FIG. 7 or to stepwise change mesa widths as shown in FIG. 8. Also in these cases, it is possible to change refractive indexes of an active layer by properly setting a mesa width and increase the number of oscillating longitudinal modes and obtain the same advantage as the case of forming the mesa-stripe portion into a tapered shape.

Thus, in the first embodiment, the mesa-stripe portion of the BH-type DFB semiconductor laser device is formed into a tapered shape so that the number of longitudinal modes in the half band width Δλh of the oscillation wavelength spectrum 15 becomes two or more. However, the effective refraction indexes may be changed to make the number of longitudinal modes in the half band width Δλh of an oscillation wavelength spectrum 15 two or more. The refraction indexes may be changed by forming the ridge portion of a ridge-type DFB semiconductor laser device into a tapered shape so that. This case is explained below as a second embodiment of the present invention.

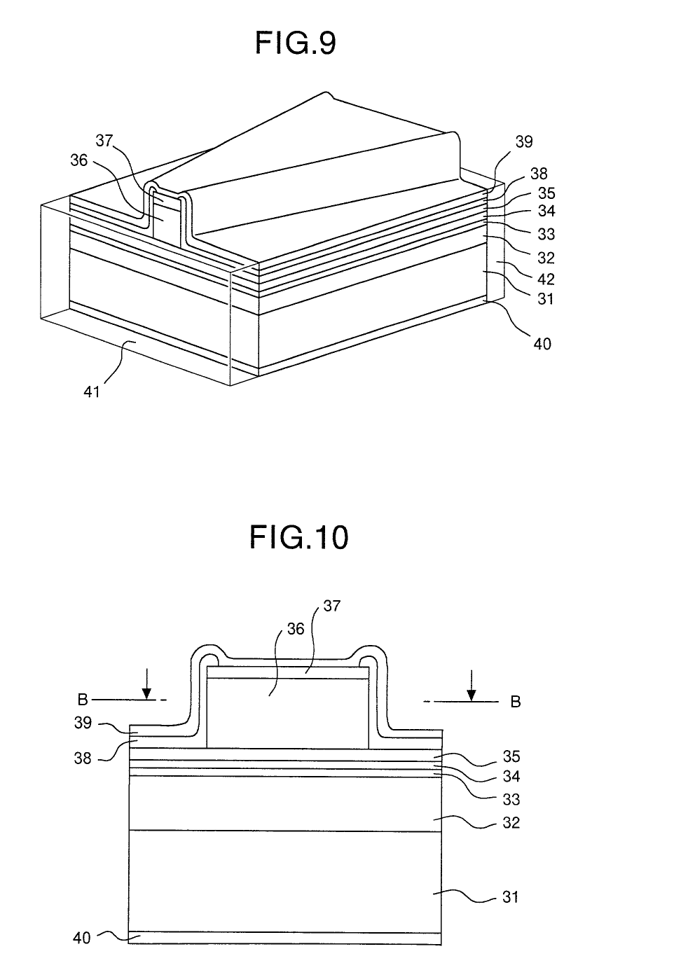

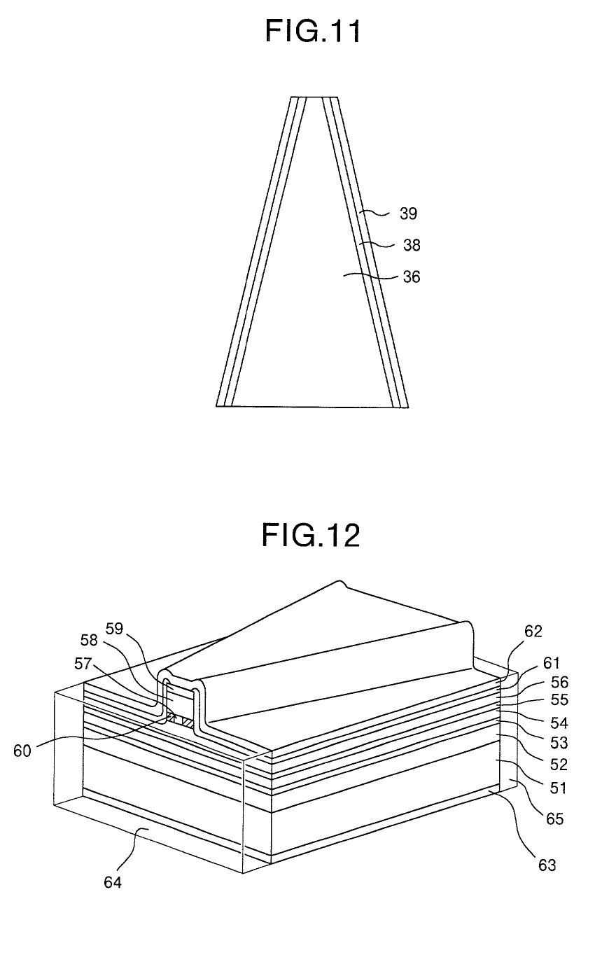

FIG. 9 is a perspective view showing a schematic configuration of the semiconductor laser device of the second embodiment. Moreover, FIG. 10 is a sectional view of the semiconductor laser device shown in FIG. 9 in the direction vertical to the resonator of the system and FIG. 11 is a sectional view of the semiconductor laser device shown in FIG. 10, taken along the line B-B of FIG. 10.

This semiconductor laser device is constituted by forming an n-InP cladding layer 32, an n-GaInAsP optical waveguide layer 33 with a diffraction grating formed on it, an n-InP layer 34, and a GRIN-SCH-MQW active layer 35 in order on an n-InP substrate 31. Moreover, a p-InP cladding layer 36 and a p-GaInAs layer 37 are formed in order as a ridge portion. Furthermore, an SiNx film 38 is formed by avoiding the upper face of the ridge portion and a p-side electrode 39 is formed on the upper faces of the ridge portion and SiNx film 38 and an n-side electrode 40 is formed on the back of the n-InP substrate 31.

Moreover, an emission-side reflective coating 41 having a low light reflectance of 1% or less is formed on the light emission facet and a reflective coating 42 having a high reflectance of 70% or more is formed on the light reflection facet. Furthermore, the ridge portion formed by the p-InP cladding layer 36 and p-GaInAsP layer 37 is formed into a tapered shape in which the ridge width decreases nearby the emission-side reflective coating 41 and the mesa width increases nearby the reflective coating 42.

In this case, the light produced in the GRIN-SCH-MQW active layer 35 of the optical resonator formed by the emission-side reflective coating 41 and reflective coating 42 reflects from the reflective coating 42 and is emitted as a laser beam through the emission-side reflective coating 41. The laser beam can output a laser beam including two or more oscillating longitudinal modes by combining and setting oscillation parameters of a tapered shape, the grating pitch of a diffraction grating, then-GaInAsP optical waveguide layer 33, and the length of a resonator.

The semiconductor laser device of the second embodiment is fabricated in a manner as explained below. First, the n-InP cladding layer 32, n-GaInAsP optical-waveguide layer 33, and n-InP layer 34 are formed in order on the n-InP substrate 31 grown by MOCVD. Then, a grating having a predetermined pitch is patterned by an electron-beam exposure system to form the grating on the n-InP layer 34 and n-GaInAsP optical-waveguide layer 33 through chemical etching.

Moreover, a diffraction grating formed on the n-GaInAsP optical-waveguide layer 33 is embedded by the n-InP layer 34 grown by MOCVD. Then, the GRIN-SCH-MQW active layer 35, p-InP cladding layer 36, and p-GaInAs layer 37 are formed in order.

Then, a tapered SiO₂ film is formed and the p-GaInAs layer 37 and p-InP cladding layer 36 are etched by using the SiO₂ film as a mask to form the tapered ridge portion shown in FIG. 11. Moreover, the SiNx film 38 is formed on the surface of the substrate excluding the upper face of the ridge portion. Then, the n-InP substrate 31 is polished up to a thickness of approximately 100 μm to form the p-side electrode 39 and n-side electrode 40. Then, the substrate is cleaved to form the emission-side reflective coating 41 having a low light reflectance of 1% or less on the light emission facet. Moreover, the reflective coating 42 having a high light reflectance of 70% or more is formed on the light reflection facet.

In the semiconductor laser device of the second embodiment, by forming the ridge portion into a tapered shape, a range in which current is injected into the GRIN-SCH-MQW active layer 35 is tapered and excitation occurs in the range in which current is injected. Therefore, because effective refraction indexes Neff are changed in the resonator direction similarly to the case of the first embodiment, the number of oscillating longitudinal modes increases. Moreover, by setting the grating pitch of the diffraction grating and the tapered shape, it is possible to set the number of oscillating longitudinal modes of a laser beam to a desired value.

According to the semiconductor laser device of the second embodiment, the ridge portion formed by the p-InP cladding layer 36 and p-GaInAs layer 37 is formed into a tapered shape and the grating pitch of the diffraction grating and the tapered shape are set so that a plurality of oscillating longitudinal modes are included in an oscillation wavelength spectrum. Therefore, when using the ridge portion as the exciting light source of a Raman amplifier, a laser beam is emitted which makes it possible to obtain a stable and high Raman gain without causing induced Brillouin scattering.

It is not always necessary to entirely form the ridge portion into a tapered shape but it is permitted to locally form the portion into a tapered shape or stepwise change mesa widths. Also in these cases, by setting a ridge width, it is possible to change refraction indexes of an active layer and increase the number of oscillating longitudinal modes and obtain the same advantage as the case of forming a ridge portion into a tapered shape.

In the first embodiment, the mesa-stripe portion of the BH-type DFB semiconductor laser device is formed into a tapered shape so that the number of longitudinal modes of the oscillation wavelength spectrum becomes two or more. However, half band widths Δλh of the oscillation wavelength spectrum 15 may be changed to make the number of longitudinal modes in the half band width Δλh two or more. The wavelength spectrum 15 may be changed by forming the ridge portion of an oxide-layer-confinement-type semiconductor laser device, that is, the width of the opening of a current confinement layer constituted of an oxide film into a tapered shape. This case is explained below as a third embodiment of the present invention.

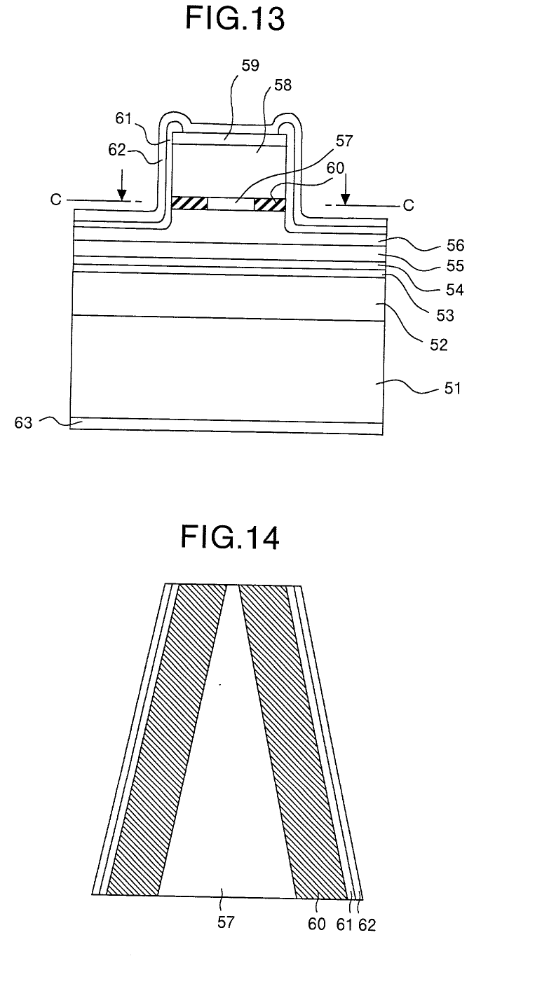

FIG. 12 is a perspective view showing a schematic configuration of the semiconductor laser device of the third embodiment. Moreover, FIG. 13 is a sectional view of the semiconductor laser device shown in FIG. 12 in the direction vertical to the resonator direction of the system and FIG. 14 is a sectional view of the semiconductor laser device shown in FIG. 13, taken along the line C-C in FIG. 13.

The semiconductor laser device is constituted by forming an n-InP cladding layer 52, an n-GaInAsP optical waveguide layer 53 with a diffraction grating formed on it, an n-InP layer 54, and a GRIN-SCH-MQW active layer 55 in order on an n-InP substrate 51. Moreover, a p-In cladding layer 56, a p-AlInAs oxidizable layer 57, a p-InP cladding layer 58, and a p-GaInAs layer 59 are formed in order as a ridge portion. Furthermore, an SiNx film 61 is formed by avoiding the upper face of the ridge portion, a p-side electrode 62 is formed on the upper face of the SiNx film 61, and an n-side electrode 63 is formed on the back of the n-InP substrate 51.

Furthermore, an emission-side reflective coating 64 having a low light reflectance of 1% or less is formed on the light emission facet and a reflective coating 65 having a high reflectance of 70% or more is formed on the light reflection facet. Furthermore, the ridge portion formed by the p-InP cladding layer 56, p-AlInAs oxidizable layer 57, p-InP cladding layer 58, and p-GaInAs layer 59 is formed into a tapered shape in which the ridge width decreases nearby the emission-side reflective coating 64 and the mesa width increases nearby the reflective coating 65. Furthermore, the p-AlInAs oxidizable layer 57 forms an Al oxide film layer 60 because the vicinity of side faces of the ridge portion is oxidized.

In this case, the light produced in the GRIN-SCH-MQW active layer 55 formed between the emission-side reflective coating 64 and reflective coating 65 is reflected from the reflective coating 65 and emitted as a laser beam through the emission-side reflective coating 64. The laser beam can output a laser beam including two or more oscillating longitudinal modes by combining and setting oscillation parameters of a tapered shape, the grating pitch of a diffraction grating, the n-GaInAsP optical-waveguide layer 53, and the length of a resonator.

The semiconductor laser device of the third embodiment is fabricated in a manner as explained below. First, the n-InP cladding layer 52, n-GaInAsP optical-waveguide layer 53, and n-InP layer 54 are formed in order on the n-InP substrate 51 grown by MOCVD. Then, a grating having a predetermined pitch is patterned by using an electron-beam exposure system to form the grating on the n-InP layer 54 and n-GaInAsP optical-waveguide layer 53 through chemical etching.

Moreover, the diffraction grating formed on the n-GaInAsP optical-waveguide layer 53 is flatly embedded by the n-InP layer 54 grown by MOCVD. Then, the GRIN-SCH-MQW active layer 55, p-InP cladding layer 56, p-AlInAs oxidizable layer 57, p-InP cladding layer 58, and p-GaInAs layer 59 are formed in order.

Then, a tapered SiO₂ film is formed and the p-GaInAs layer 59, p-InP cladding layer 58, p-AlInAs oxidizable layer 57, and p-InP cladding layer 56 are etched up to the middle of them by using the SiO₂ film as a mask to form the tapered ridge portion shown in FIGS. 13 and 14. Moreover, the AlInAs oxidizable layer 57 is oxidized up to 3 μm per side from the both side faces of the layer 57 by applying heat treatment to the layer 57 at a temperature of approximately 500° C. for 150 min in water vapor to form an Al oxide-film layer 60. Thereby, the AlInAs oxidizable layer 57 saved from oxidation serves as a current injection area.

Then, the SiNx film 61 is formed on the upper face of the substrate except the upper face of the ridge portion to polish the n-InP substrate 51 up to a thickness of approximately 100 μm. Moreover, the p-side electrode 62 and n-side electrode 63 are formed. Then, the substrate is cleaved to form the emission-side reflective coating 64 having a low light reflectance of 1% or less on the light emission facet. Moreover, the reflective coating 65 having a high reflectance of 70% or more is formed on the light reflection facet.

Though the AlInAs oxidizable layer 57 is conductive, the Al oxide-film layer 60 is insulative and its refractive index is smaller than that of the AlInAs oxidizable layer 57. Therefore, the Al oxide-film layer 60 makes it possible to confine current and light. For example, when the ridge width of the p-InP cladding layer 58 is 8 μm nearby the emission-side reflective coating 41 and 12 μm nearby the reflective coating 65, the AlInAs oxidizable layer 57 becomes a tapered shape of 2 μm nearby the emission-side reflective coating 41 and a tapered shape of 6 μm nearby the reflective coating 65 and functions as a current injection area.

In the semiconductor laser device of the third embodiment, by forming the width of the opening of the current confinement layer made of an oxide film into a tapered shape, the range in which current is injected into the GRIN-SCH-MQW active layer 55 is tapered and excitation occurs in the range into which current is injected. Therefore, because effective refraction indexes Neff are changed in the resonator direction, the number of oscillating longitudinal modes increases. Moreover, by setting the grating pitch of the diffraction grating, the tapered shape, and the thickness of the oxide-film layer, it is possible to set the number of oscillating longitudinal modes of a laser beam to a desired value.

Furthermore, the width of the opening of the current confinement layer made of an oxide layer is tapered and the grating pitch of the diffraction grating, the tapered shape, and the thickness of the oxide-film layer are set so that a plurality of oscillating longitudinal modes are included in the half bandwidth of an oscillating wavelength spectrum. Therefore, when using the semiconductor laser device as the exciting light source of a Raman amplifier, it is possible to obtain a stable and high Raman gain without causing induced Brillouin scattering.

It is not always necessary to entirely form the opening of the current confinement layer made of an oxide layer in the ridge portion into a tapered shape, as shown in FIG. 14, but it is permitted to locally form the opening into a tapered shape or stepwise change the mesa widths. Also in these cases, it is possible to change refraction indexes of the active layer and increase the number of oscillating longitudinal modes by setting the opening width of the current confinement layer made of an oxide layer and obtain the same advantage as the case of forming the ridge portion into a tapered shape.

Moreover, it is permitted to form the Al oxide-film layer 60 by forming a tapered channel on the AlInAs oxidizable layer 57 and embedding it and then, forming a ridge portion, and exposing and oxidizing the AlInAs layer 57. Thereby, the controllability of an oxidation width is improved.

In the second embodiment, the present invention is applied to the ridge-type DFB semiconductor laser device including the diffraction grating in the ridge portion. However, the present invention may be applied to a ridge-type DFB semiconductor laser device including the diffraction grating on the side of the ridge portion. The ridge portion may be tapered to make the number of longitudinal modes in a half band width Δλh of an oscillation wavelength spectrum two or more. This case is explained below as a fourth embodiment of the present invention.

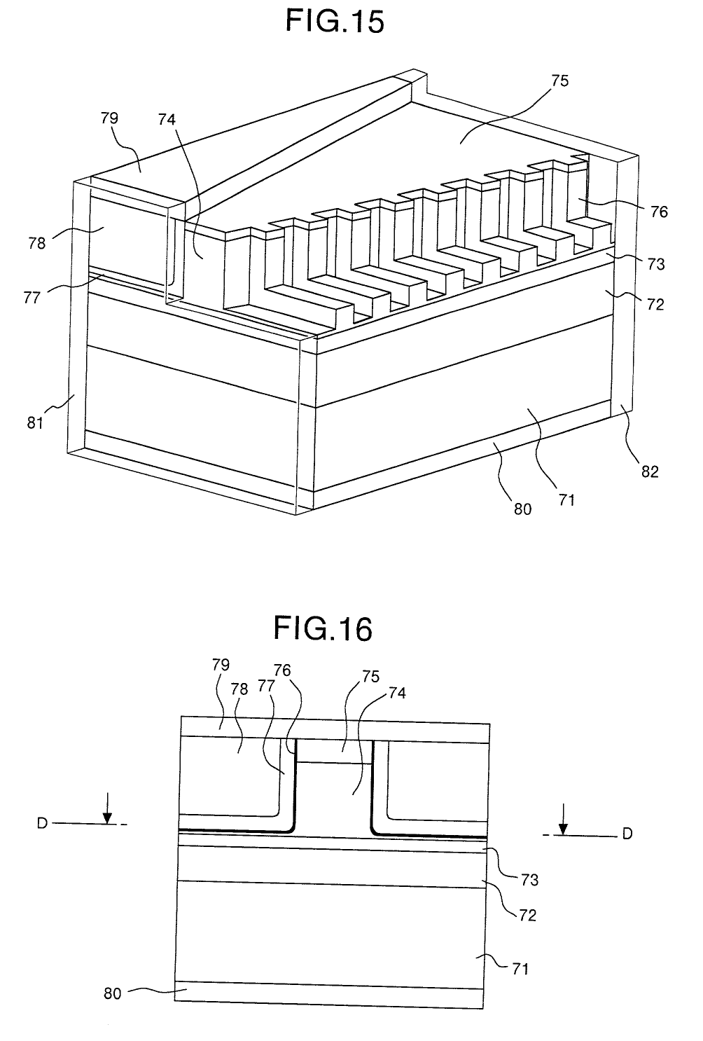

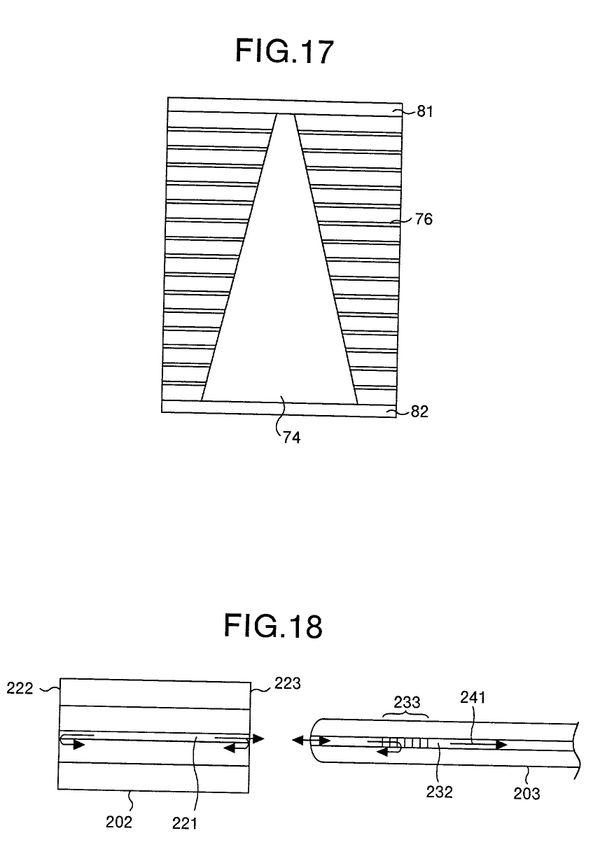

FIG. 15 is a perspective view showing a schematic configuration of the semiconductor laser device of the fourth embodiment. Moreover, FIG. 16 is a sectional view of the semiconductor laser device shown in FIG. 15 in the direction vertical to the direction of the resonator of the system and FIG. 17 is a sectional view of the semiconductor laser device shown in FIG. 16, taken along the line D-D in FIG. 16.

The above semiconductor laser device is constituted by forming an n-InP cladding layer 72 and a GRIN-SCH-MQW active layer 73 on an n-InP substrate 71. Moreover, a p-InP cladding layer 74 and a p-GaInAs contact layer 75 are formed in order as a ridge portion. Furthermore, an SiNx film 77 and polyimide 78 are formed in order by avoiding the side face of the ridge portion. Furthermore, a p-side electrode 79 is formed on the upper faces of the ridge portion and polyimide 78 and an n-side electrode 80 is formed on the lower face of the n-InP substrate 71.

Furthermore, a diffraction grating 76 is formed on the p-InP cladding layer 74 on the upper face of an off ridge present at side faces and the both sides of the ridge portion. Furthermore, an emission-side reflective coating 81 having a low light reflectance of 1% or less is formed on the light emission facet and a reflective coating 82 having a high reflectance of 70% or more is formed on the light reflection facet. Furthermore, the ridge portion formed by the p-InP cladding layer 74 and p-GaInAs contact layer 75 is formed into a tapered shape in which the ridge width decreases nearby the emission-side reflective coating 81 and the mesa width increases nearby the reflective coating 82.

In this case, the light produced in the GRIN-SCH-MQW active layer 73 of an optical resonator formed by the emission-side reflective coating 81 and the reflective coating 82 is reflected from the reflective coating 72 and emitted as a laser beam through the emission-side reflective coating 71. The laser beam can output a laser beam including two or more oscillating longitudinal modes by combining and setting oscillation parameters of a tapered shape, the grating pitch of a diffraction grating, and the length of a resonator.

The semiconductor laser device of the fourth embodiment is fabricated in a manner as explained below. First, then-InP cladding layer 72, GRIN-SCH-MQW active layer 73, p-InP cladding layer 74, and p-GaInAs contact layer 75 are formed in order on the n-InP substrate 71 grown by MOCVD. Then, a tapered SiO₂ film is formed and the p-GaInAs contact layer 75 and p-InP cladding layer 74 are etched by using the SiO₂ film as a mask to form a tapered ridge portion.

Then, a grating having a predetermined pitch is patterned on side faces of the ridge portion and the upper face of the off ridge by an electron-beam exposure system to form the diffraction grating 76 through chemical etching. Moreover, the SiNx film 77 and polyimide 78 are formed on side faces of the ridge portion and the upper face of the off ridge and the n-InP substrate 71 is polished up to a thickness of approximately 100 μm to form the p-side electrode 79 and n-side electrode 80. Then, the substrate is cleaved to form the emission-side reflective coating 81 having a low light reflectance of 1% or less on the light emission facet. Moreover, the reflective coating 82 having a high light reflectance of 70% or more is formed on the light reflection facet.

In the semiconductor laser device of this fourth embodiment, the diffraction grating 76 is formed on side faces of the ridge portion and the upper face of the off ridge, the light penetrated from the ridge portion senses the diffraction grating, reflection occurs for a specified wavelength decided in accordance with the pitch of the diffraction grating, and laser oscillation of a selected wavelength is performed.

Moreover, effective refraction indexes Neff are changed in the resonator direction by forming the ridge portion into a tapered shape and oscillation is performed in a plurality of longitudinal modes. It is possible to set the number of oscillating longitudinal modes to a desired value by setting the grating pitch of the diffraction grating 76 and the tapered shape.

Furthermore, because the diffraction grating 76 is formed on the side faces of the ridge portion and the upper face of the off ridge, it is possible to obtain a semiconductor laser device suitable for the exciting light source of a Raman amplifier through a simple process.

According to the fourth embodiment, when using the semiconductor laser device as the exciting light source of a Raman amplifier, the system emits a laser beam capable of obtaining a stable and high Raman gain without causing induced Brillouin scattering because the ridge portion formed by the p-InP cladding layer 74 and p-GaInAs contact layer 75 is formed into a tapered shape and the grating pitch of the diffraction grating and the tapered shape are set so that a plurality of oscillating longitudinal modes are included in the half band width of an oscillation wavelength spectrum.

As shown in FIG. 17, it is not always necessary to entirely from the ridge portion into a tapered shape but it is permitted to locally form the ridge portion into a tapered shape or stepwise change mesa widths. Also in these cases, it is possible to change refractive indexes of an active layer and increase the number of oscillating longitudinal modes by setting a ridge width and obtain the same advantage as the case of forming the ridge portion into a tapered shape.

As described above, according to the one aspect of this invention, the semiconductor laser device has the tapered mesa-stripe portion and outputs the laser beam including two or more oscillating longitudinal modes by combining and setting oscillation parameters of the tapered shape, the grating pitch of the diffraction grating, the optical waveguide including the active layer, and the length of the resonator. Therefore, an advantage is obtained that a stable and high-output mesa-stripe-type semiconductor laser device suitable for a Raman amplification light source can be realized.

According to another aspect of this invention, the semiconductor laser device has the continuously-stepwise mesa stripe portion and outputs the laser beam including two or more oscillating longitudinal modes by combining and setting oscillation parameters of the continuously-stepwise shape, the grating pitch of the diffraction grating, the optical waveguide including the active layer, and the length of the resonator. Therefore, an advantage is obtained that a stable and high-output BH-type semiconductor laser device suitable for a Raman amplification light source can be realized.

According to another aspect of this invention, the semiconductor laser device has the tapered ridge portion and outputs the laser beam including two or more oscillating longitudinal modes by combining and setting oscillation parameters of the tapered shape, the grating pitch of the diffraction grating, the optical waveguide including the active layer, and the length of the resonator. Therefore, an advantage is obtained that a stable and high-output ridge-waveguide-type semiconductor laser device suitable for a Raman amplification light source can be realized.

According to still another aspect of this invention, the semiconductor laser device has the continuously-stepwise mesa stripe portion and outputs the laser beam including two or more oscillating longitudinal modes by combining and setting oscillation parameters of the continuously-stepwise shape, the grating pitch of the diffraction grating, the optical waveguide including the active layer, and the length of the resonator. Therefore, an advantage is obtained that a stable and high-output ridge-waveguide-type semiconductor laser device suitable for a Raman amplification light source can be realized.

According to still another aspect of this invention, the semiconductor laser device has the opening of the current confinement layer made of the tapered oxide film and outputs the laser beam including two or more oscillating longitudinal modes by combining and setting oscillation parameters of the tapered shape, the grating pitch of the diffraction grating, the optical waveguide including the active layer, and the length of the resonator. Therefore, an advantage is obtained that a stable and high-output oxide-layer-confinement-type semiconductor laser device suitable for a Raman amplification light source can be realized.

According to still another aspect of this invention, the semiconductor laser device has the opening of the current confinement layer made of the continuously-stepwise oxide film and outputs the laser beam including two or more oscillating longitudinal modes by combining and setting oscillation parameters of the continuously-stepwise shape, the grating pitch of the diffraction grating, the optical waveguide including the active layer, and the length of the resonator. Therefore, an advantage is obtained that a stable and high-output oxide-layer-confinement-type semiconductor laser device suitable for a Raman amplification light source can be realized.

Furthermore, an advantage is obtained that the number of oscillating longitudinal modes can be easily increased to two or more by setting the resonator length formed by the active layer to 600 μm or more and decreasing the interval between oscillating longitudinal modes.

Furthermore, an advantage is obtained that the laser beam suitable for the Raman amplification light source can be efficiently output because the light reflection facet reflects 70% or more of the laser beam and the laser beam reflected from the light emission facet is decreased to 1% or less.

Furthermore, an advantage is obtained that a large margin can be obtained in the cleavage process and the stable and high-output semiconductor laser device suitable for the Raman amplification light source can be obtained at a high yield.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor laser device comprising:
a light emission facet for emitting laser;
a light reflection facet for reflecting the laser;
a first reflective coating provided on said light emission facet;
a second reflective coating provided on said light reflection facet;
an active layer formed between said first reflective coating and said second reflective coating;
a resonator, formed because of said active layer being sandwiched between said light emission and light reflection facets, for resonating the laser;
a diffraction grating provided nearby said active layer; and
a mesa-stripe portion that includes at least the active layer, wherein
said mesa-stripe portion is formed into a tapered shape such that width of said mesa-stripe portion continuously expands in a portion or entire area between said first and second reflective coatings, and
a laser beam including two or more oscillating longitudinal modes is output in accordance with setting of a combination of oscillation parameters of the tapered shape of said mesa-stripe portion, the grating pitch of said diffraction grating, and an optical waveguide including said active layer, and the length of said resonator.

2. The semiconductor laser device according to claim 1, wherein the resonator length is 600 μm or more.

3. The semiconductor laser device according to claim 1, wherein reflectance of the first reflective coating is 1% or less, and reflectance of the second reflective coating is 70% or more.

4. The semiconductor laser device according to claim 1, wherein
ends of the first and the second reflective coatings of the opening of the current confinement layer constituted of the mesa-stripe portion, the ridge portion, or the oxide film respectively have a margin area keeping the width of the end of the tapered shape or the continuously-stepwise shape.

5. A semiconductor laser device comprising:
a light emission facet for emitting laser;
a light reflection facet for reflecting the laser;
a first reflective coating provided on said light emission facet;
a second reflective coating provided on said light reflection facet;
an active layer formed between said first reflective coating and said second reflective coating;
a resonator, formed because of said active layer being sandwiched between said light emission and light reflection facets, for resonating the laser;
a diffraction grating provided nearby said active layer; and
a mesa-stripe portion that includes at least the active layer, wherein
said mesa-stripe portion is formed into a tapered shape such that width of said mesa-stripe portion expands in steps in a portion or entire area between said first and second reflective coatings, and
a laser beam including two or more oscillating longitudinal modes is output in accordance with setting of a combination of oscillation parameters of the tapered shape of said mesa-stripe portion, the grating pitch of said diffraction grating, and an optical waveguide including said active layer, and the length of said resonator.

6. The semiconductor laser device according to claim 5, wherein the resonator length is 600 μm or more.

7. The semiconductor laser device according to claim 5, wherein reflectance of the first reflective coating is 1% or less, and reflectance of the second reflective coating is 70% or more.

8. The semiconductor laser device according to claim 5, wherein
ends of the first and the second reflective coatings of the opening of the current confinement layer constituted of the mesa-stripe portion, the ridge portion, or the oxide film respectively have a margin area keeping the width of the end of the tapered shape or the continuously-stepwise shape.

9. A semiconductor laser device comprising:
a light emission facet for emitting laser;
a light reflection facet for reflecting the laser;
a first reflective coating provided on said light emission facet;
a second reflective coating provided on said light reflection facet;
an active layer formed between said first reflective coating and said second reflective coating;
a resonator, formed because of said active layer being sandwiched between said light emission and light reflection facets, for resonating the laser;
a diffraction grating provided nearby said active layer; and
a ridge portion for controlling a current to be injected into said active layer, wherein
said ridge portion is formed into a tapered shape such that width of said ridge portion continuously expands in a portion or entire area between said first and second reflective coatings, and
a laser beam including two or more oscillating longitudinal modes is output in accordance with setting of a combination of oscillation parameters of the tapered shape of said ridge portion, the grating pitch of said diffraction grating, and an optical waveguide including said active layer, and the length of said resonator.

10. The semiconductor laser device according to claim 9, wherein the resonator length is 600 μm or more.

11. The semiconductor laser device according to claim 9, wherein reflectance of the first reflective coating is 1% or less, and reflectance of the second reflective coating is 70% or more.

12. The semiconductor laser device according to claim 9, wherein
ends of the first and the second reflective coatings of the opening of the current confinement layer constituted of the mesa-stripe portion, the ridge portion, or the oxide film respectively have a margin area keeping the width of the end of the tapered shape or the continuously-stepwise shape.

13. A semiconductor laser device comprising:
a light emission facet for emitting the laser;
a light reflection facet for reflecting the laser;
a first reflective coating provided on said light emission facet;
a second reflective coating provided on said light reflection facet;
an active layer formed between said first reflective coating and said second reflective coating;
a resonator, formed because of said active layer being sandwiched between said light emission and light reflection facets, for resonating the laser;
a diffraction grating provided nearby said active layer; and
a ridge portion for controlling a current to be injected into said active layer, wherein
said ridge portion is formed into a tapered shape such that width of said ridge portion expands in steps in a portion or entire area between said first and second reflective coatings, and
a laser beam including two or more oscillating longitudinal modes is output in accordance with setting of a combination of oscillation parameters of the tapered shape of said ridge portion, the grating pitch of said diffraction grating, and an optical waveguide including said active layer, and the length of said resonator.

14. The semiconductor laser device according to claim 13, wherein the resonator length is 600 μm or more.

15. The semiconductor laser device according to claim 13, wherein reflectance of the first reflective coating is 1% or less, and reflectance of the second reflective coating is 70% or more.

16. The semiconductor laser device according to claim 13, wherein
ends of the first and the second reflective coatings of the opening of the current confinement layer constituted of the mesa-stripe portion, the ridge portion, or the oxide film respectively have a margin area keeping the width of the end of the tapered shape or the continuously-stepwise shape.

17. A semiconductor laser device comprising:
a light emission facet for emitting laser;
a light reflection facet for reflecting the laser;
a first reflective coating provided on said light emission facet;
a second reflective coating provided on said light reflection facet;
an active layer formed between said first reflective coating and said second reflective coating;
a resonator, formed because of said active layer being sandwiched between said light emission and light reflection facets, for resonating the laser;
a current confinement layer constituted of an oxide film for controlling a current to be injected into said active layer, wherein
opening of said current confinement layer is formed into a tapered shape such that width of the opening continuously expands in a portion or entire area between said first and second reflective coatings, and
a laser beam including two or more oscillating longitudinal modes is output in accordance with setting of a combination of oscillation parameters of the tapered shape of the opening of said current confinement layer, the grating pitch of said diffraction grating, and an optical waveguide including said active layer, and the length of said resonator.

18. The semiconductor laser device according to claim 17, wherein the resonator length is 600 μm or more.

19. The semiconductor laser device according to claim 17, wherein reflectance of the first reflective coating is 1% or less, and reflectance of the second reflective coating is 70% or more.

20. The semiconductor laser device according to claim 17, wherein
ends of the first and the second reflective coatings of the opening of the current confinement layer constituted of the mesa-stripe portion, the ridge portion, or the oxide film respectively have a margin area keeping the width of the end of the tapered shape or the continuously-stepwise shape.

21. A semiconductor laser device comprising:
a resonator for resonating laser;
a light emission facet for emitting the laser;
a light reflection facet for reflecting the laser;
a first reflective coating provided on said light emission facet;
a second reflective coating provided on said light reflection facet;
an active layer formed between said first reflective coating and said second reflective coating;
a resonator, formed because of said active layer being sandwiched between said light emission and light reflection facets, for resonating the laser;
a current confinement layer constituted of an oxide film for controlling a current to be injected into said active layer, wherein
opening of said current confinement layer is formed into a tapered shape such that width of the opening expands in steps in a portion or entire area between said first and second reflective coatings, and
a laser beam including two or more oscillating longitudinal modes is output in accordance with setting of a combination of oscillation parameters of the tapered shape of the opening of said current confinement layer, the grating pitch of said diffraction grating, and an optical waveguide including said active layer, and the length of said resonator.

22. The semiconductor laser device according to claim 21, wherein the resonator length is 600 μm or more.

23. The semiconductor laser device according to claim 21, wherein reflectance of the first reflective coating is 1% or less, and reflectance of the second reflective coating is 70% or more.

24. The semiconductor laser device according to claim 21, wherein
ends of the first and the second reflective coatings of the opening of the current confinement layer constituted of the mesa-stripe portion, the ridge portion, or the oxide film respectively have a margin area keeping the width of the end of the tapered shape or the continuously-stepwise shape.
